(19) United States
(12) Patent Application Publication
(10) Pub. No.: US 2005/0285105 A1
(43) Pub. Date: Dec. 29, 2005

(54) Pressure inspector and method for inspecting liquid crystal display panels

(75) Inventor: Tian-Sheng Xiao, Shenzhen (CN)

Correspondence Address: WEI TE CHUNG;FOXCONN INTERNATIONAL, INC., 1650 MEMOREX DRIVE, SANTA CLARA, CA, 95050, US

(73) Assignee: INNOLUX DISPLAY CORP.

(21) Appl. No.: 11/168,233

(22) Filed: Jun. 27, 2005

(30) Foreign Application Priority Data
Jun. 25, 2004 (TW) 93118536

(51) Int. Cl. G01R 31/26; H01L 23/58; H01L 21/66; H01L 29/10

(52) U.S. Cl. 257/48; 438/16

(57) ABSTRACT

A pressure inspector (1) for inspecting at least one liquid crystal display panel includes a roller (11), and a holder (12) holding the roller such that the roller is rotatable in the holder and can roll along the liquid crystal display panel. When the pressure inspector works, the rollers are positioned on a display surface of the LCD panel. Then, a certain pressure is applied to the handle to roll the rollers along the LCD panel. As the rollers roll along the LCD panel, one or more of the fan-shaped vanes extrude on the potential pressure dot if either of the rollers passes over a potential pressure dot. Accordingly, the existence of pressure dots is detected. By using the pressure inspector, the pressure dots in the liquid crystal display panel to be tested can be determined and found out quickly and correctly.

### FIELD OF THE INVENTION

The present invention relates to a pressure inspector and a method, and particularly to a pressure inspector and a method for inspecting liquid crystal display panels.

### BACKGROUND

Because a liquid crystal display (LCD) device has the merits of being thin, light in weight, and drivable by a low voltage, it is extensively employed in various electronic devices. A typical LCD device includes an LCD panel, which including two transparent substrates parallel to each other, a liquid crystal layer disposed between the two substrates.

A first electrode layer includes an active matrix and is disposed on a surface of one of the two substrates adjacent to the liquid crystal layer, and a second electrode layer includes a transparent Indium Tin Oxide (ITO) common electrode and is arranged on a surface of the other substrate adjacent to the liquid crystal layer. The active matrix includes a plurality of thin film transistors arranged in a matrix, and each thin film transistor connects with a signal line, a gate line and a pixel electrode. A voltage can be applied to the pixel electrode via cooperation of the signal line and the gate line, and an electric field can be created between the pixel electrode and the common electrode. The electric field controls twisting directions of the liquid crystal molecules so that determining whether light beams pass through the liquid crystal layer or not.

To get an LCD device with a high quality performance, a circuitry on the first and second electrode layers are becoming more accurate and denser. However, due to complicated processes and a great variety of processing conditions, yield of the LCD device is limited. A type of defect named a dot defect is one of reasons limiting the yield of the LCD device.

The dot defects derive from failures of the first or/and second electrode layers in the LCD panel. Generally, the dot defects include an obvious dot defect and a hidden dot defect. Occurrence of the obvious dot defect usually dues to one or more corresponding pixel electrodes being open or shorting, which results in regular dark or light.

The hidden dot defect usually dues to the poor electrode contact or faulty welding in the first or/and second electrode layers. Contaminations on the ITO layer may also cause a hidden dot defect, but it is difficult to find the defect in naked eye just after the LCD panel has been made, and the defect is named a pressure dot.

If omitting the pressure dot, some LCD devices having potential defects may be regarded as a finer product and used in various fields. When the LCD device works in some certain situations, such as hitting, touching the LCD panel, the potential pressure dot may become an obvious dot defect and causes deterioration of an image quality of the LCD device.

In order to find the pressure dot in processes of manufacturing an LCD device, a method of manual extrusion an LCD panel of the LCD device to be tested is employed. The method is performed as the following steps: turning on a power of an LCD device tested, modulating the LCD device and obtaining a state of regular dark or light, extruding a display surface of the LCD panel of the LCD device with a finger. If there is a pressure dot in a portion extruded, a circuitry defect corresponding to the pressure dot appears after the pressure from a finger disappears. Sometimes extrusion on the contaminations on the LCD panel may damage an insulating layer among conductor materials, and cause electric leakage. In general, a circuitry corresponding to the pressure dot becomes unsteady after the pressure from a finger disappears. The pressure dot can be found twinkling, thus a pressure dot is determined.

Otherwise, the hidden dot defect dues to the poor electrode contact or faulty welding in the first or/and second electrode layers may result in a corresponding circuit malfunction. Consequently, some dot defects in a state of regular dark or light may be regarded as pressure dots, the defect may be found out via the method described above.

However, the method of manually extruding an LCD panel to be tested has some disadvantages. On one hand, the whole display surface of the LCD panel tested needs to be extruded by a finger, which costs rather much time and efforts. On the other hand, because a finger is so tender that pressure applied on a larger area, it may be difficult to find out all potential pressure dots.

It is desired to provide a pressure inspector for inspecting a liquid crystal display panel.

### SUMMARY

In one preferred embodiment, a pressure inspector for inspecting a liquid crystal display panel includes at least one roller, and a holder holding the roller such that the roller is rotatable in the holder and can roll along the liquid crystal display panel.

In one preferred embodiment, a method for inspecting a liquid crystal display panel includes steps of turning on a power supply of an liquid crystal display panel to be tested, modulating the liquid crystal display panel and obtaining a state of regular dark or light, positioning the roller of the pressure inspector on a liquid crystal display panel to be tested, applying a certain pressure to the liquid crystal panel to roll the roller on the liquid crystal display panel.

The pressure inspector and method for inspecting a liquid crystal display panel provided herein have the following advantages. In one embodiment of the invention, the pressure inspector is used for inspecting a pressure dot, the roller is positioned on a display surface of the LCD panel, and a certain pressure is applied to the LCD panel to roll the roller along the LCD panel. After the pressure of the pressure inspector pass over the LCD panel, one or more pressure dots can be found out if there is one or more pressure dots exist in the liquid crystal display panel. Thus the pressure dots can be determined and found out quickly and correctly.

Other advantages and novel features of various embodiments will become more apparent from the following detailed description when taken in conjunction with the accompanying drawings.

### BRIEF DESCRIPTION OF THE DRAWINGS

FIG. 1 is a schematic, isometric exploding view of a pressure inspector according to a first embodiment of the present invention.

FIG. 2 is an assembled view of the pressure inspector of FIG. 1.

FIG. 3 is an enlarged, side view of a roller of the pressure inspector of FIG. 1.

FIG. 4 is an enlarged, side view of a detector of the pressure inspector of FIG. 1.

FIG. 5 is an enlarged, front view of an axle of the pressure inspector of FIG. 1.

FIG. 6 is an isometric view of a pressure inspector according to a second embodiment of the present invention.

FIG. 7 is an isometric view of a pressure inspector according to a third embodiment of the present invention.

FIG. 8 is an isometric view of a pressure inspector according to a fourth embodiment of the present invention.

FIG. 9 is an isometric view of a pressure inspector according to a fifth embodiment of the present invention.

### DETAILED DESCRIPTION OF PREFERRED EMBODIMENTS

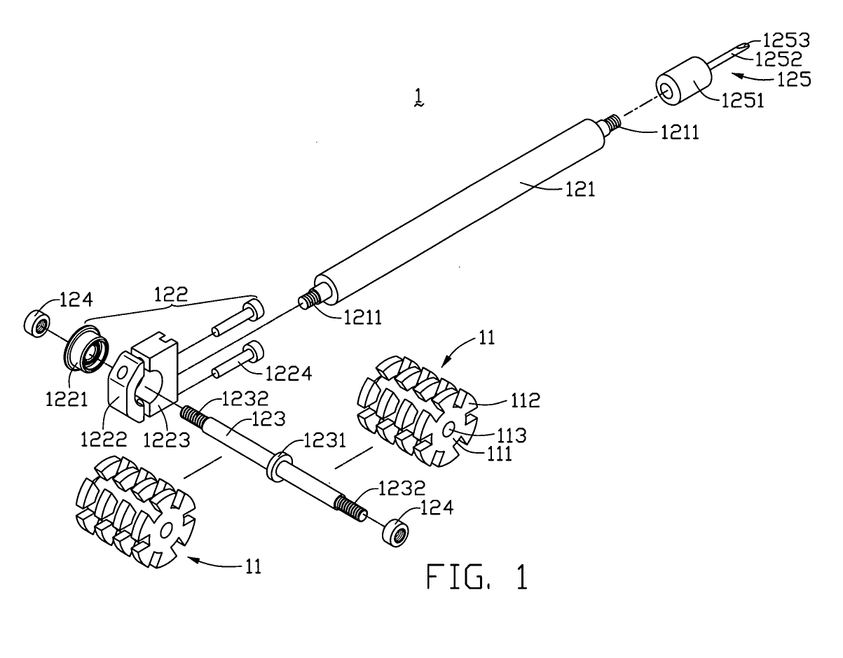

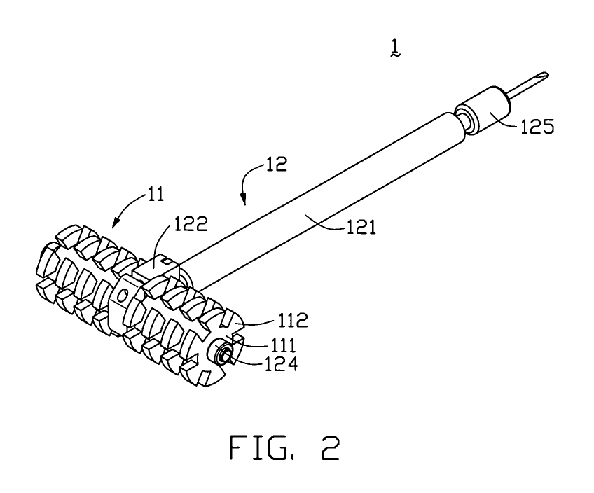

FIGS. 1 and 2 show a pressure inspector 1 according to the first embodiment of the invention. The pressure inspector 1 includes two rollers 11 and a holder 12. Each roller 11 includes a body 111, and a plurality of fan-shaped vanes 112 extending radially from the body 111. An axial through hole 113 is defined in the roller 11. The holder 12 includes a handle 121, an axle 123 mating in the through holes 113 of the rollers 11, and a housing 122 secured around a middle of the axle 123. The handle 121 is fixed on the housing 122 such that the handle 121 is perpendicular to the axle 123. The axle 123 is fixed in the through holes 113 of the rollers 11, and can rotate in the housing 122.

Referring to FIGS. 1 and 5, an annular bead 1231 is formed around a middle of the axle 123. Each roller 11 abuts a respective side of the bead 1231. Opposite ends of the axle 123 protrude out from the rollers 11 respectively, with each such end having a first thread 1232. Two screw caps 124 are screwed onto the first threads 1232 respectively, so that the rollers 11 are rotatably attached to the holder 12.

The housing 122 includes two separate fastening blocks 1222 and 1223, a bearing 1221, and a pair of fasteners 1224. The bearing 1221 is engaged around the bead 1231, with an inner diameter of the bearing 1221 being slightly larger than an outer diameter of the bead 1231. The bead 1231 is thus rotatable within the bearing 1221. The fasteners 1224 fasten the fastening blocks 1222 and 1223 together, such that the fastening blocks 1222 and 1223 are fixed around the bearing 1221 and hold the bearing 1221 therebetween.

The handle 121 has a second thread 1211 on each of two opposite ends thereof. A bottom one of the second threads 1211 is screwed into a threaded hole (not visible) of the fastening block 1223, such that the handle 121 is fixed to the housing 122. The handle 121 is thus perpendicular to the axle of the rollers 11.

Referring to FIGS. 1 and 4, a detector 125 is fixed on at top end of the handle 121. The detector 125 has a fixed end 1251 and an operating end 1252. The fixed end 1251 is enlarged, and defines a threaded hole (shown in dashed lines in FIG. 4) therein. Thus the fixed end 1251 can be screwed onto a top one of the second threads 1211 of the handle 121, so that the detector 125 is fixed on the handle 121. A distal tip of the operating end 1252 is tapered, and defines a slanted tangent surface 1253 thereat.

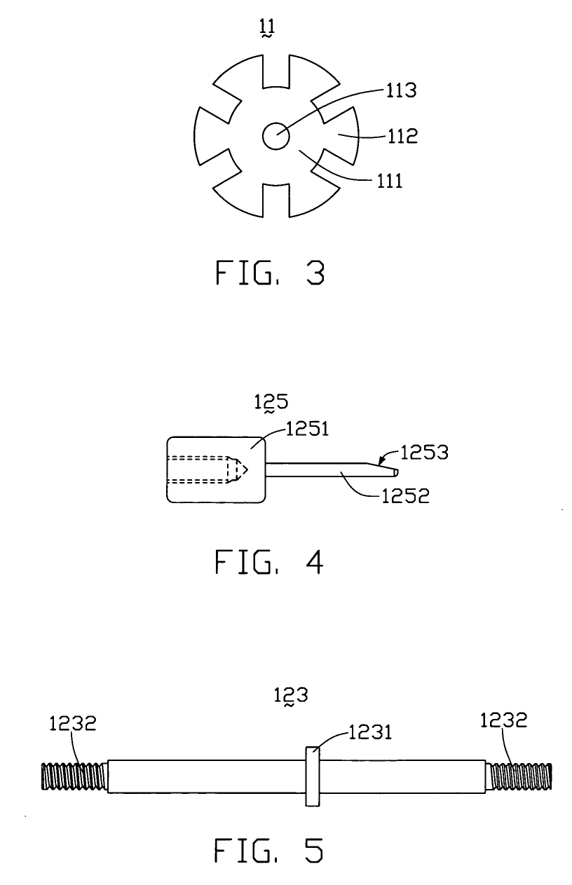

Referring to FIGS. 1 and 3, the fan-shaped vanes 112 all have the same size and shape. The fan-shaped vanes 112 can be considered as consisting of a plurality of parallel groups of fan-shaped vanes 112. Each group of fan-shaped vanes 112 has all the fan-shaped vanes 112 extending radially from a same center point of the body 111. In each group of fan-shaped vanes 112, intervals between adjacent fan-shaped vanes 112 are uniform. The groups of fan-shaped vanes 112 are arranged along an axial direction of the body 111 at uniform intervals, with the fan-shaped vanes 112 in each group being directly opposite the fan-shaped vanes 112 of one or more adjacent groups. An outer periphery of the housing 122 is generally smaller than a circumference defined by the fan-shaped vanes 112 in each group of fan-shaped vanes 112.

The rollers 11 and detector 125 are made of hard plastic. The holder 12 is made of a hard material such as iron, steel, aluminum, hard plastic, hard organic material, a metallic alloy, or the like.

When the pressure inspector 1 is used for inspecting pressure dots in an LCD panel under test, firstly, the rollers 11 are positioned on a display surface of the LCD panel. Secondly, the handle 121 is held by an operator, and a certain pressure is applied to the handle 121 to roll the rollers 11 along the LCD panel. As the rollers 11 roll along the LCD panel, one or more of the fan-shaped vanes 112 extrude on the potential pressure dot if either of the rollers 11 passes over a potential pressure dot. Accordingly, the existence of pressure dots is detected.

Further, an axial length of each roller 11 may be configured according to particular requirements, such as the size of the LCD panel being tested. As the rollers 11 are rolled along, all pressure dots in an area covered by the rollers 11 can be detected. Particularly in the case of large LCD panels, it is convenient and quick to detect all the pressure dots, and few pressure dots are likely to be missed. Additionally, the pressure inspector 1 has a relatively simple structure and low cost.

Additionally, if one or more parts of the pressure inspector 1 are damaged or need inspection or replacement, the rollers 11, the handle 121 and the detector 125 can be readily disassembled and then reassembled. Further, the pressure inspector 1 can be used for determining whether a regular light/dark dot is a pressure dot or not, and for more precisely locating the pressure dot.

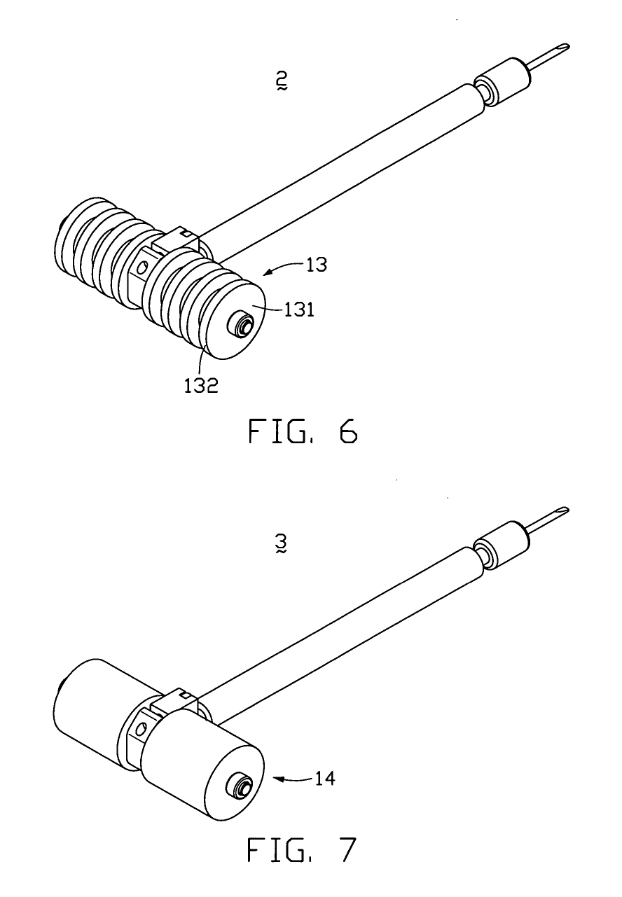

Referring to FIG. 6, a pressure inspector 2 according to the second embodiment of the invention is shown. The pressure inspector 2 includes a pair of rollers 13 and the holder 12. Each roller 13 includes a body 131, and a plurality of parallel wheels 132 formed around the body 131. The wheels 132 all have the same size and shape. Intervals between adjacent wheels 132 are uniform.

Referring to FIG. 7, a pressure inspector 3 according to the third embodiment of the invention is shown. The pressure inspector 3 includes a pair of cylindrical rollers 14.

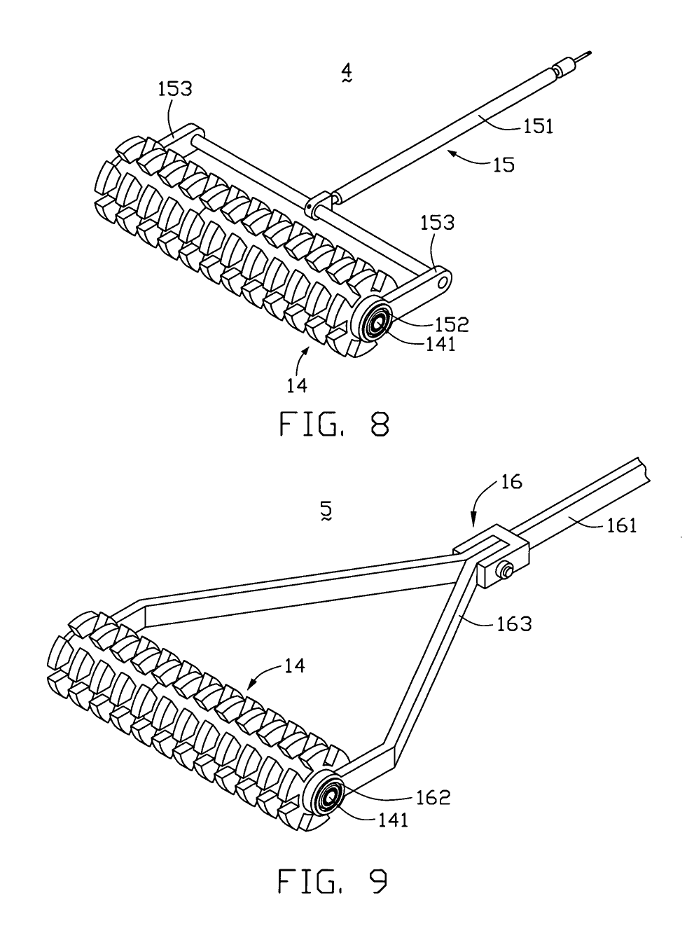

Referring to FIG. 8, a pressure inspector 4 according to the fourth embodiment of the invention is shown. The pressure inspector 4 is similar to the pressure inspector 1 of the first embodiment, and includes a single roller 14 and a holder 15. Each of two ends of the roller 14 has a protrusion 141 extending outwardly along an axial direction of the roller 14. The holder 15 includes a handle 151, a crossbar (not labeled), and two arms 153 extending in a same direction from opposite ends of the crossbar. An end of each arm 153 has a housing 152 secured around a corresponding protrusion 141. Thus the two arms 153 hold the roller 14 therebetween, with the roller 14 being rotatable in the housings 152.

Referring to FIG. 9, a pressure inspector 5 according to the fifth embodiment of the invention is shown. The pressure inspector 5 is similar to the pressure inspector 4 of the fourth embodiment, and includes the roller 14 and a holder 16. The holder 16 includes a handle 161 and two bent arms 163. An end of each bent arm 163 has a housing 162 secured around the corresponding protrusion 141. Thus the two bent arms 163 hold the roller 14 therebetween, with the roller 14 being rotatable in the housings 162. The bent arms 163 can be conveniently assembled and disassembled.

In alternative embodiments, the axle of the holder of the pressure inspector may be rotatable in the through hole of the roller or the through holes of the rollers.

In other alternative embodiments, the axle of the holder of the pressure inspector may be rotatable in the through hole of the roller or the through holes of the rollers. Each roller may be formed as a body having at least one annular groove defined therein. At least one housing of the holder includes an annular wheel, with the annular wheel engaged in the annular groove.

In further alternative embodiments, the handle and the housing of a holder may be formed as a single body. Further or alternatively, the handle may be welded onto the housing. Similarly, the handle, the arms, and the housing of a holder may be formed as a single body. Further or alternatively, the handle, the arms and the housing may be welded together.

It is believed that the present embodiments and their advantages will be understood from the foregoing description, and it will be apparent that various changes may be made thereto without departing from the spirit and scope of the invention or sacrificing all of its material advantages, the examples hereinbefore described merely being preferred or exemplary embodiments of the invention.

1. A pressure inspector for inspecting a liquid crystal display panel, comprising:
at least one roller; and
a holder holding the roller such that the roller is rotatable in the holder and can roll along the liquid crystal display panel.

2. The pressure inspector according to claim 1, wherein the roller defines an axial through hole along an axial direction thereof, the holder comprises an axle mating in the through hole, and the holder further comprises a housing engaged around a middle of the axle, and a handle portion perpendicular to the axle.

3. The pressure inspector according to claim 2, wherein the at least one roller is two rollers, the rollers are engaged around opposite sides of the axle, and the axles are rotatable in the axial through holes.

4. The pressure inspector according to claim 2, wherein the axle is fixed in the axial through hole, and may rotate in the housing.

5. The pressure inspector according to claim 4, wherein the handle portion and the housing are formed as a body.

6. The pressure inspector according to claim 4, wherein the handle portion is welded on the housing.

7. The pressure inspector according to claim 4, wherein the handle portion is fixed on the housing by bolts or screws.

8. The pressure inspector according to claim 4, wherein the roller has two ends and the axle extends out of the two ends of the roller, and each end of the roller has a proof structure thereon to hold the roller at a predetermined position.

9. The pressure inspector according to claim 1, wherein an annular groove is disposed in the middle of the roller, and the holder is a structure and comprises a handle portion having two ends, and one end of the handle portion is engaged around the annular groove rotatably.

10. The pressure inspector according to claim 1, wherein the roller has two ends, and each end of the roller has a protrusion forward the axial direction of the roller; the holder comprises a handle portion and two bent arms, ends of the bent arms secure with two protrusions respectively to make the bent arms hold and roll the roller.

11. The pressure inspector according to claim 1, wherein the holder comprises a handle portion having two ends, and one end holds the roller, and the other end is tapered and has a tangent surface.

12. The pressure inspector according to claim 11, wherein the tapered end is made of hard plastic.

13. The pressure inspector according to claim 1, wherein a plurality of group of fan-shaped vanes are arranged along the axial direction of the roller, and sizes and shapes of the fan-shaped vanes, intervals among the fan-shaped vanes are uniform, and each group of fan-shaped vane defines a suppositional circumference.

14. The pressure inspector according to claim 1, wherein a plurality of wheels are arranged on the roller along the axial direction of the roller, and sizes and shapes of the wheels, and intervals among the wheels are uniform.

15. The pressure inspector according to claim 1, wherein the roller is made of hard plastic.

16. The pressure inspector according to claim 1, wherein the roller has an adjustable size along the axial direction of the roller.

17. A method employing a pressure inspector for inspecting a liquid crystal display panel, the pressure inspector comprising a roller, and a holder holding and rolling the roller around an axial direction of the roller on the liquid crystal display panel, the method comprising steps of:
turning on a power supply of a liquid crystal display panel to be tested;
modulating the liquid crystal display panel and obtaining a state of regular dark or light;
positioning the roller of the pressure inspector on a liquid crystal display panel tested; and
applying a certain pressure to the liquid crystal panel to roll the roller on the liquid crystal display panel.

18. A method of testing an LCD (Liquid Crystal Display) panel via pressure, the method comprising steps of:
turning on a liquid crystal display to obtain a state of regular dark or light;
positioning a roller of a pressure inspector on a liquid crystal display panel wherein said roller is rotated about an axis and is dimensioned along said axis with a relatively significant distance so as to apply forces upon a lengthened area rather than a limited area defined by hand exam; and
applying a certain pressure to the liquid crystal panel to roll the roller on the liquid crystal display panel.
